(19) United States
(12) Patent Application Publication
(10) Pub. No.: US 2021/0391507 A1
(43) Pub. Date: Dec. 16, 2021

(54) LIGHT-EMITTING CHIP CARRYING STRUCTURE AND METHOD OF MANUFACTURING THE SAME

(71) Applicant: ASTI GLOBAL INC., TAIWAN, Taichung City (TW)

(72) Inventors: CHIEN-SHOU LIAO, New Taipei City (TW); CHIH-CHENG WANG, Taoyuan City (TW); YU-MIN HUANG, Taoyuan City (TW); SHAO-WEI HUANG, Taoyuan City (TW)

(21) Appl. No.: 17/343,744

(22) Filed: Jun. 10, 2021

(30) Foreign Application Priority Data
Jun. 16, 2020 (TW) 109120194

(51) Int. Cl. H01L 33/48; H01L 33/00; H01L 33/62

(52) U.S. Cl. CPC H01L 33/486; H01L 2933/0066; H01L 33/62; H01L 33/005

(57) ABSTRACT

A light-emitting chip carrying structure and a method of manufacturing the same are provided. The method includes transferring a plurality of light-emitting chips to a circuit substrate; driving a leveling substrate to concurrently press the light-emitting chip by a carrier device such that a plurality of distances each defined between a light-emitting surface of each of the light-emitting chips and a top surface of the circuit substrate are the same; fixing the light-emitting chips on the circuit substrate by a heating device while the light-emitting chips are pressed by the leveling substrate; and then removing the leveling substrate by the carrier device. Therefore, the light-emitting surfaces of the light-emitting chips relative to the top surface of the circuit substrate have the same flatness, and the light-emitting surfaces of the light-emitting chips are disposed on the same plane.

### CROSS-REFERENCE TO RELATED PATENT APPLICATION

This application claims the benefit of priority to Taiwan Patent Application No. 109120194, filed on Jun. 16, 2020. The entire content of the above identified application is incorporated herein by reference.

Some references, which may include patents, patent applications and various publications, can be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip carrying structure and a method of manufacturing the same, and more particularly to a light-emitting chip carrying structure and a method of manufacturing the same.

### BACKGROUND OF THE DISCLOSURE

In the related art, an LED chip is usually electrically connected to a circuit board through a plurality of solder balls. However, when the solder balls are heated and begin melting, the LED chip that is disposed on the solder balls will be caused to tilt due to the unevenness in the thicknesses of the melting solder balls.

### SUMMARY OF THE DISCLOSURE

In response to the above-referenced technical inadequacies, the present disclosure provides a light-emitting chip carrying structure and a method of manufacturing the same.

In one aspect, the present disclosure provides a light-emitting chip carrying structure, which includes a circuit substrate and a light-emitting group. The circuit substrate includes a plurality of conductive pads and a plurality of conductive materials respectively disposed on the conductive pads. The light-emitting group includes a plurality of light-emitting chips. Each of the light-emitting chips includes two conductive contacts respectively electrically contacting the two corresponding conductive materials, and a plurality of distances each defined between a light-emitting surface of each of the light-emitting chips and a top surface of the circuit substrate are the same, so that the light-emitting surfaces of the light-emitting chips relative to the top surface of the circuit substrate have the same flatness, and the light-emitting surfaces of the light-emitting chips are located in a same plane.

In another aspect, the present disclosure provides a method of manufacturing a light-emitting chip carrying structure, which includes: transferring a plurality of light-emitting chips to a circuit substrate such that each of the light-emitting chips is electrically connected to the circuit substrate through two of a plurality of initial conductive materials; driving a leveling substrate to concurrently press the light-emitting chips by a carrier device such that a plurality of distances each defined between a light-emitting surface of each of the light-emitting chips and a top surface of the circuit substrate are the same; while the light-emitting chips are pressed by the leveling substrate, using a heating device to concurrently heat a plurality of conductive materials so as to fix each of the light-emitting chips on the two corresponding conductive materials; and then removing the leveling substrate by the carrier device.

In yet another aspect, the present disclosure provides a method of manufacturing a light-emitting chip carrying structure, which includes: transferring a plurality of light-emitting chips to a circuit substrate; driving a leveling substrate to concurrently press the light-emitting chips by a carrier device such that a plurality of distances each defined between a light-emitting surface of each of the light-emitting chips and a top surface of the circuit substrate are the same; while the light-emitting chips are pressed by the leveling substrate, using a heating device to fix each of the light-emitting chips on the circuit substrate; and then removing the leveling substrate by the carrier device.

Therefore, by virtue of “the circuit substrate including a plurality of conductive pads and a plurality of conductive materials respectively disposed on the conductive pads”, “the light-emitting group including a plurality of light-emitting chips, and each of the light-emitting chips including two conductive contacts respectively electrically contacting the two corresponding conductive materials” and “a plurality of distances each defined between a light-emitting surface of each of the light-emitting chips and a top surface of the circuit substrate being the same”, the light-emitting surfaces of the light-emitting chips relative to the top surface of the circuit substrate have the same flatness, and the light-emitting surfaces of the light-emitting chips are located in the same plane.

Furthermore, by virtue of “driving a leveling substrate to concurrently press the light-emitting chips by a carrier device, so that a plurality of distances each defined between a light-emitting surface of each of the light-emitting chips and a top surface of the circuit substrate are the same” and “while the light-emitting chips are pressed by the leveling substrate, using a heating device to fix the light-emitting chips on the circuit substrate”, the light-emitting surfaces of the light-emitting chips relative to the top surface of the circuit substrate have the same flatness, and the light-emitting surfaces of the light-emitting chips are located in the same plane.

These and other aspects of the present disclosure will become apparent from the following description of the embodiment taken in conjunction with the following drawings and their captions, although variations and modifications therein can be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flowchart of a method of manufacturing a light-emitting chip carrying structure according to the present disclosure.

FIG. 2 is a schematic view of step S100(A) of the method of manufacturing the light-emitting chip carrying structure according to a first embodiment of the present disclosure.

FIG. 3 is a schematic view of step S100, step S100(B) and step S100(D) of the method of manufacturing the light-emitting chip carrying structure according to the first embodiment of the present disclosure.

FIG. 4 is a schematic view of step S102 of the method of manufacturing the light-emitting chip carrying structure according to the first embodiment of the present disclosure.

FIG. 5 is a schematic view of step S104 of the method of manufacturing the light-emitting chip carrying structure according to the first embodiment of the present disclosure.

FIG. 6 is a schematic view of step S106 of the method of manufacturing the light-emitting chip carrying structure according to the first embodiment of the present disclosure, and is also a schematic view of the light-emitting chip carrying structure according to the first embodiment of the present disclosure.

FIG. 7 is a schematic view of step S100(C) of the method of manufacturing the light-emitting chip carrying structure according to the first embodiment of the present disclosure.

FIG. 8 is a schematic view of step S200(A) of a method of manufacturing the light-emitting chip carrying structure according to a second embodiment of the present disclosure.

FIG. 9 is a schematic view of step S200(B) of the method of manufacturing the light-emitting chip carrying structure according to the second embodiment of the present disclosure.

FIG. 10 is a schematic view of step S200 of the method of manufacturing the light-emitting chip carrying structure before being performed according to the second embodiment of the present disclosure.

FIG. 11 is a schematic view of step S200 of the method of manufacturing the light-emitting chip carrying structure after being performed according to the second embodiment of the present disclosure.

FIG. 12 is a schematic view of step S202 of the method of manufacturing the light-emitting chip carrying structure according to the second embodiment of the present disclosure.

FIG. 13 is a schematic view of step S204 of the method of manufacturing the light-emitting chip carrying structure according to the second embodiment of the present disclosure.

FIG. 14 is a schematic view of step S206 of the method of manufacturing the light-emitting chip carrying structure according to the second embodiment of the present disclosure, and is also a schematic view of the light-emitting chip carrying structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

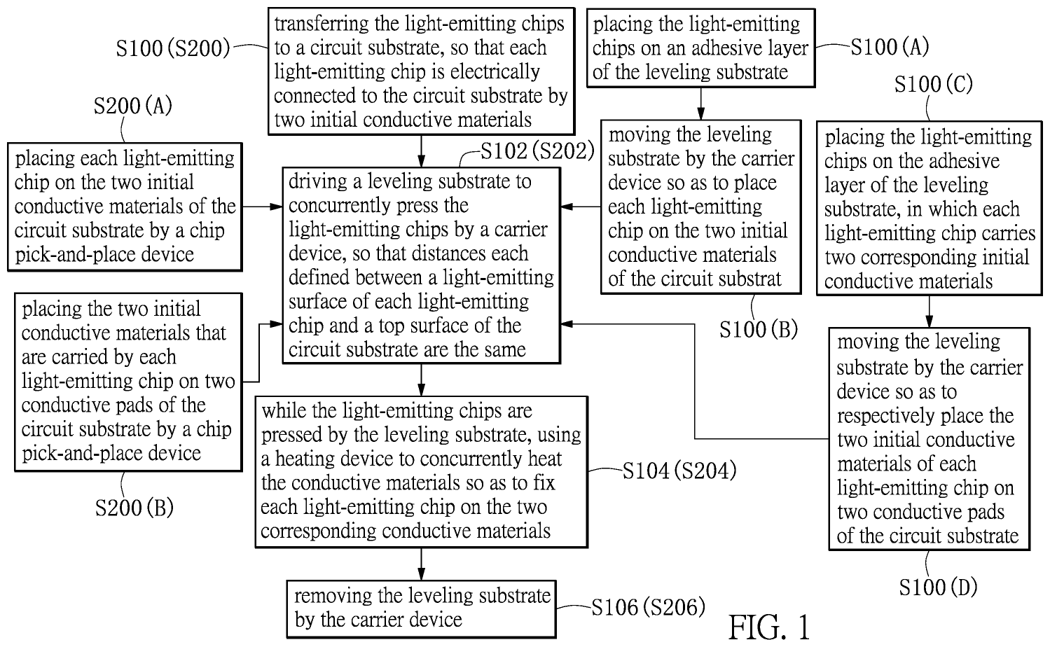

Referring to FIG. 1 to FIG. 14, the present disclosure provides a light-emitting chip carrying structure S including a circuit substrate 1 and a light-emitting group 2. The circuit substrate 1 includes a plurality of conductive pads 100 and a plurality of conductive materials B respectively disposed on the conductive pads 100. In addition, the light-emitting group 2 includes a plurality of light-emitting chips 20, and each of the light-emitting chips 20 includes two conductive contacts 200 respectively electrically contacting two corresponding conductive materials B. Therefore, a plurality of distances D each defined between a light-emitting surface 2000 of each of the light-emitting chips 20 and a top surface 1000 of the circuit substrate 1 are the same, so that the light-emitting surfaces 2000 of the light-emitting chips 20 relative to the top surface 1000 of the circuit substrate 1 have the same flatness, and the light-emitting surfaces 2000 of the light-emitting chips 20 are located in a same plane P.

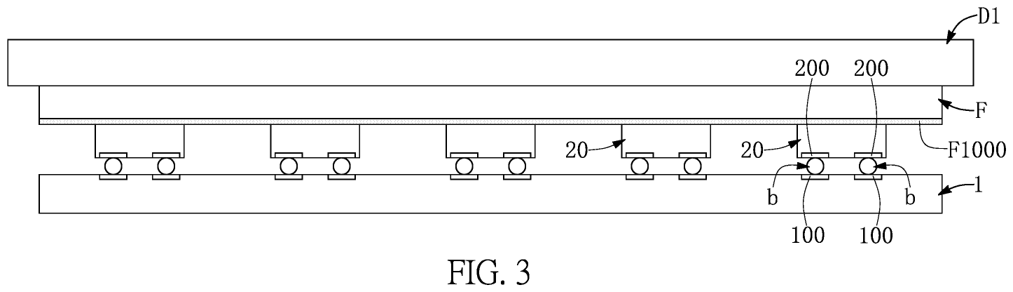

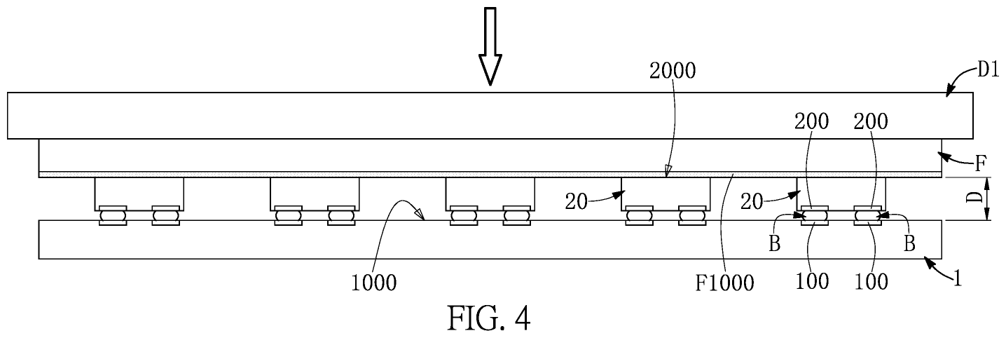

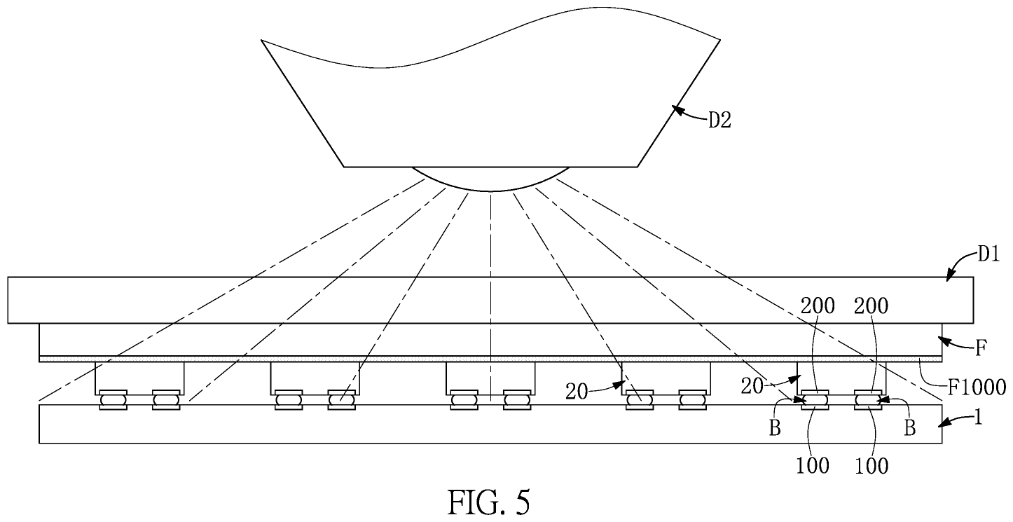

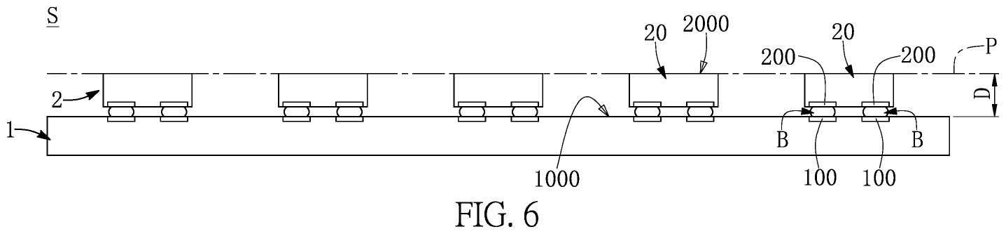

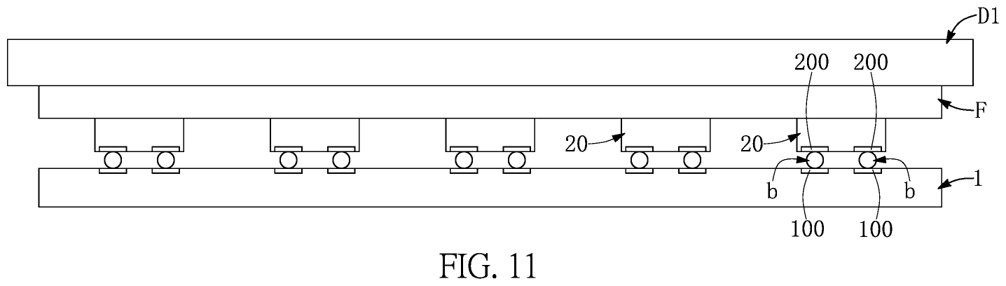

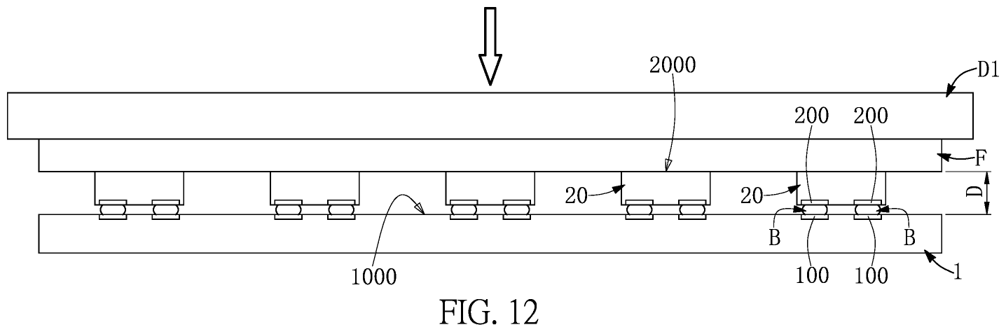

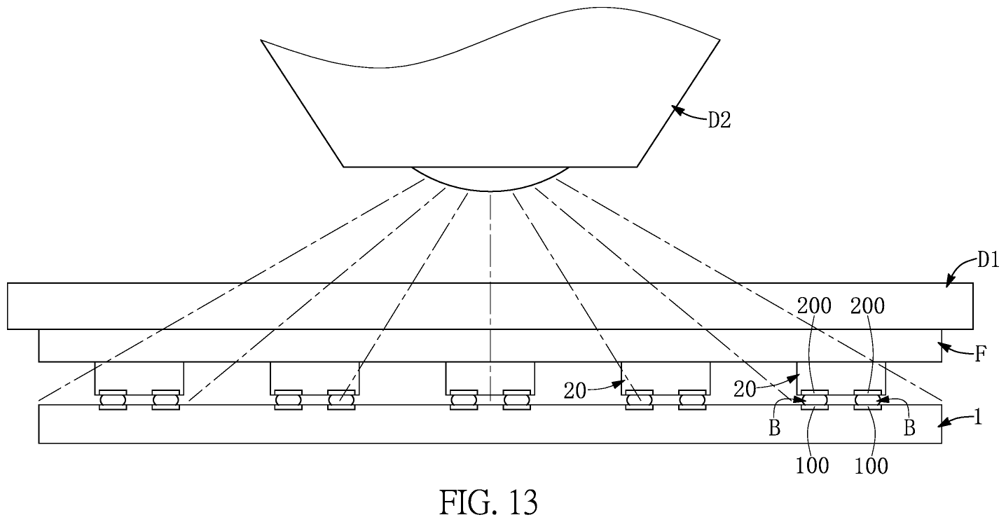

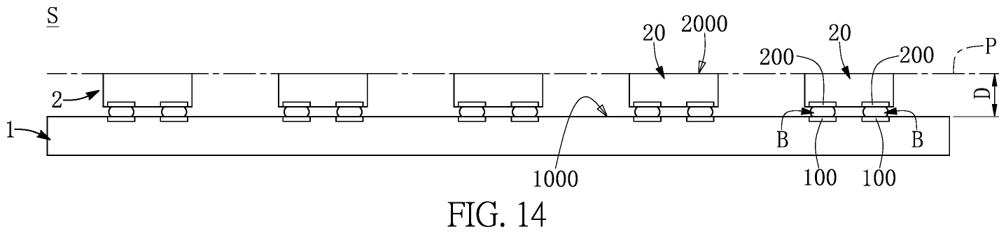

Referring to FIG. 1 to FIG. 14, the present disclosure provides a method of manufacturing a light-emitting chip carrying structure S, which includes: firstly, referring to FIG. 1 and FIG. 3 (or referring to FIG. 1 and FIG. 11), transferring a plurality of light-emitting chips 20 to a circuit substrate 1; next, referring to FIG. 1 and FIG. 4 (or referring to FIG. 1 and FIG. 12), driving a leveling substrate F (or a flattering substrate) to concurrently press the light-emitting chips 20 by a carrier device D1 such that a plurality of distances D each defined between a light-emitting surface 2000 of each of the light-emitting chips 20 and a top surface 1000 of the circuit substrate 1 are the same; then referring to FIG. 1 and FIG. 5 (or referring to FIG. 1 and FIG. 13), while the light-emitting chips 20 are pressed by the leveling substrate F, using a heating device D2 to fix the light-emitting chips 20 on the circuit substrate 1; and afterwards, referring to FIG. 1 and FIG. 6 (or referring to FIG. 1 and FIG. 14), removing the leveling substrate F by the carrier device D1.

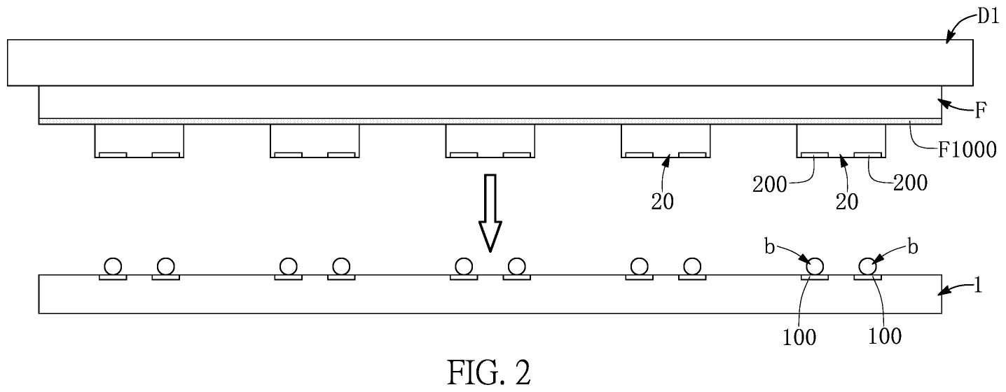

For example, referring to FIG. 2 and FIG. 3, the step of transferring the light-emitting chips 20 to the circuit substrate 1 further includes: firstly, referring to FIG. 2, placing the light-emitting chips 20 on an adhesive layer F1000 of the leveling substrate F; and then referring to FIG. 3, moving the leveling substrate F by the carrier device D1 so as to place each of the light-emitting chips 20 on two initial conductive materials b of the circuit substrate 1, so that two conductive contacts 200 of each of the light-emitting chips 20 are respectively electrically connected to two conductive pads 100 of the circuit substrate 1 through the two corresponding initial conductive materials b.

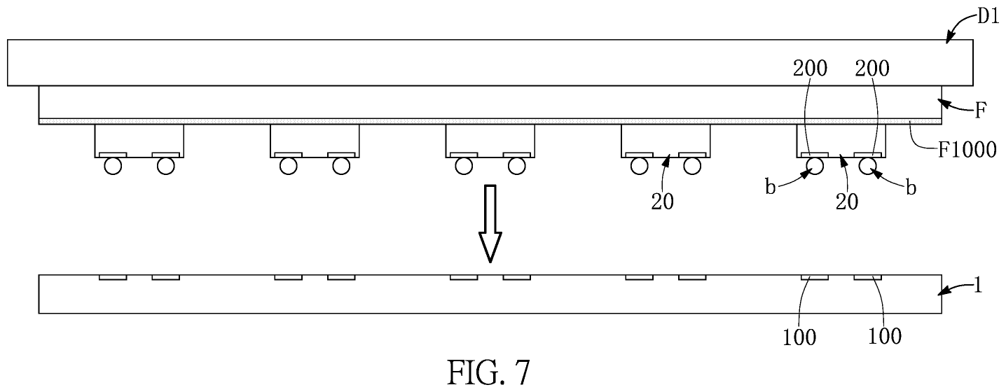

For example, referring to FIG. 3 and FIG. 7, the step of transferring the light-emitting chips 20 to the circuit substrate 1 further includes: firstly, referring to FIG. 7, placing the light-emitting chips 20 on an adhesive layer F1000 of the leveling substrate F, in which each of the light-emitting chips 20 carries two initial conductive materials b; and then referring to FIG. 3, moving the leveling substrate F by the carrier device D1 so as to respectively place the two initial conductive materials b of each of the light-emitting chips 20 on two conductive pads 100 of the circuit substrate 1, so that two conductive contacts 200 of each of the light-emitting chips 20 are respectively electrically connected to the two corresponding conductive pads 100 through the two corresponding initial conductive materials b.

### First Embodiment

Referring to FIG. 1 to FIG. 6, a first embodiment of the present disclosure provides a method of manufacturing a light-emitting chip carrying structure S, which includes: firstly, referring to FIG. 1 to FIG. 3, transferring a plurality of light-emitting chips 20 to a circuit substrate 1, so that each of the light-emitting chips 20 is electrically connected to the circuit substrate 1 by two initial conductive materials b (step S100); next, referring to FIG. 1, FIG. 3 and FIG. 4, driving a leveling substrate F to concurrently press the light-emitting chips 20 by a carrier device D1 (as shown by an arrow in FIG. 4), so that a plurality of distances D each defined between a light-emitting surface 2000 of each of the light-emitting chips 20 and a top surface 1000 of the circuit substrate 1 are the same (step S102); then referring to FIG. 1 and FIG. 5, while the light-emitting chips 20 are pressed by the leveling substrate F, using a heating device D2 to concurrently heat a plurality of conductive materials B so as to fix each of the light-emitting chips 20 on the two corresponding conductive materials B (step S104); and afterwards, referring to FIG. 1, FIG. 5 and FIG. 6, removing the leveling substrate F by the carrier device D1 (step S106). It should be noted that as shown in FIG. 5 and FIG. 6, when the conductive materials B are cured and solidified by the heating device D2, a bonding strength between the light-emitting chip 20 and the conductive material B is greater than a bonding strength between the light-emitting chip 20 and an adhesive layer F1000, so that the leveling substrate F can be separated from the light-emitting chips 20 by the carrier device D1.

More particularly, referring to FIG. 1 to FIG. 3, the step S100 of transferring the light emitting chips 20 to the circuit substrate 1 further includes: firstly, referring to FIG. 1 and FIG. 2, placing the light-emitting chips 20 on an adhesive layer F1000 of the leveling substrate F (step S100(A)); next, referring to FIG. 1 to FIG. 3, moving the leveling substrate F by the carrier device D1 so as to place each of the light-emitting chips 20 on the two initial conductive materials b of the circuit substrate 1, so that two conductive contacts 200 of each of the light-emitting chips 20 are respectively electrically connected to two conductive pads 100 of the circuit substrate 1 through the two corresponding initial conductive materials b (step S100(B)).

More particularly, referring to FIG. 1, FIG. 3 and FIG. 7, the step S100 of transferring the light emitting chips 20 to the circuit substrate 1 further includes: firstly, referring to FIG. 1 and FIG. 7, placing the light-emitting chips 20 on the adhesive layer F1000 of the leveling substrate F, in which each of the light-emitting chips 20 carries two corresponding initial conductive materials b (step S100(C)); next, referring to FIG. 1, FIG. 3 and FIG. 7, moving the leveling substrate F by the carrier device D1 so as to respectively place the two initial conductive materials b of each of the light-emitting chips 20 on two conductive pads 100 of the circuit substrate 10, so that two conductive contacts 200 of each of the light-emitting chips 20 are respectively electrically connected to the two corresponding conductive pads 100 of the circuit substrate 1 through the two corresponding initial conductive materials b (step S100(D)).

For example, in one embodiment, the light-emitting chip 20 can be a micro LED chip without a base layer, and the micro LED chip includes a p-type semiconductor layer, a light-emitting layer disposed on the p-type semiconductor layer, and an n-type semiconductor layer disposed on the light-emitting layer. In addition, in another embodiment, the light-emitting chip 20 may also be a mini LED chip that includes a base layer, a p-type semiconductor layer disposed on the base layer, a light-emitting layer disposed on the p-type semiconductor layer, and an n-type semiconductor layer disposed on the light-emitting layer. However, the aforementioned description of the first embodiment is merely an example and is not meant to limit the scope of the present disclosure.

For example, the initial conductive material b or the conductive material B can be a solder ball, solder paste or any soldering material, and the leveling substrate F can be a light-transmitting plate or an opaque plate, such as a plastic plate, a glass plate or a pressing plate made of any material. In addition, the carrier device D1 can be a nozzle, a gripper or a carrying device for carrying or driving the leveling substrate F, and the carrier device D1 does not affect the heating of the conductive materials B by the heating device D2. Moreover, the heating device D2 can be a laser heater, an infrared (IR) heater, a microwave heater or any heater for providing heat energy to heat the conductive material B. However, the aforementioned description of the first embodiment is merely an example and is not meant to limit the scope of the present disclosure.

More particularly, as shown in FIG. 6, the first embodiment of the present disclosure provides a light-emitting chip carrying structure S including a circuit substrate 1 and a light-emitting group 2. The circuit substrate 1 includes a plurality of conductive pads 100 and a plurality of conductive materials B respectively disposed on the conductive pads 100. In addition, the light-emitting group 2 includes a plurality of light-emitting chips 20, and each of the light-emitting chips 20 includes two conductive contacts 200 respectively electrically contacting the two corresponding conductive materials B. Therefore, a plurality of distances D each defined between a light-emitting surface 2000 of each of the light-emitting chips 20 and a top surface 1000 of the circuit substrate 1 are the same, so that the light-emitting surfaces 2000 of the light-emitting chips 20 relative to the top surface 1000 of the circuit substrate 1 have the same flatness, and the light-emitting surfaces 2000 of the light-emitting chips 20 are located in/on a same plane P. It should be noted that as shown in FIG. 3 and FIG. 4, when a leveling substrate F concurrently presses the light-emitting surfaces 2000 of the light-emitting chips 20 by a carrier device D1, the distances D each defined between the light-emitting surface 2000 of each of the light-emitting chips 20 and the top surface 1000 of the circuit substrate 1 are the same.

### Second Embodiment

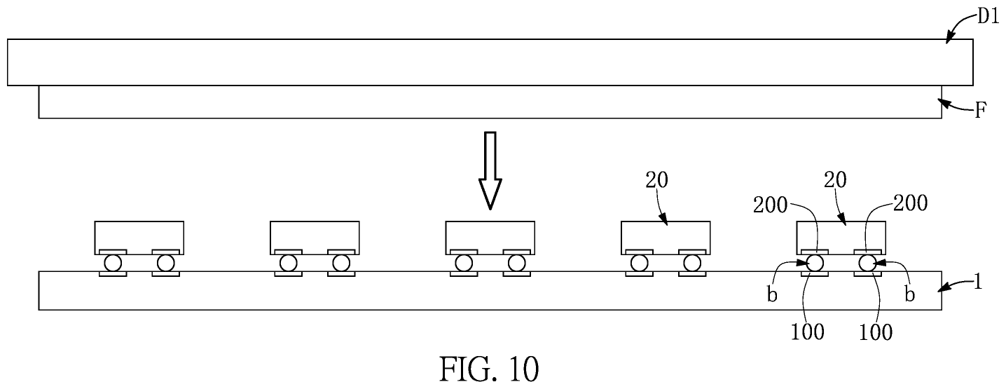

Referring to FIG. 1 and FIG. 8 to FIG. 14, a second embodiment of the present disclosure provides a method of manufacturing a light-emitting chip carrying structure S, which includes: firstly, referring to FIG. 1 and FIG. 10, transferring a plurality of light-emitting chips 20 to a circuit substrate 1, so that each of the light-emitting chips 20 is electrically connected to the circuit substrate 1 by two initial conductive materials b (step S200); next, referring to FIG. 1, FIG. 11 and FIG. 12, driving a leveling substrate F without an adhesive layer to concurrently press the light-emitting chips 20 by a carrier device D1 (as shown by an arrow in FIG. 12), so that a plurality of distances D each defined between a light-emitting surface 2000 of each of the light-emitting chips 20 and a top surface 1000 of the circuit substrate 1 are the same (step S202); then referring to FIG. 1 and FIG. 13, while the light-emitting chips 20 are pressed by the leveling substrate F, using a heating device D2 to concurrently heat a plurality of conductive materials B so as to fix each of the light-emitting chips 20 on the two corresponding conductive materials B (step S204); and afterwards, referring to FIG. 1, FIG. 13 and FIG. 14, removing the leveling substrate F by the carrier device D1 (step S206).

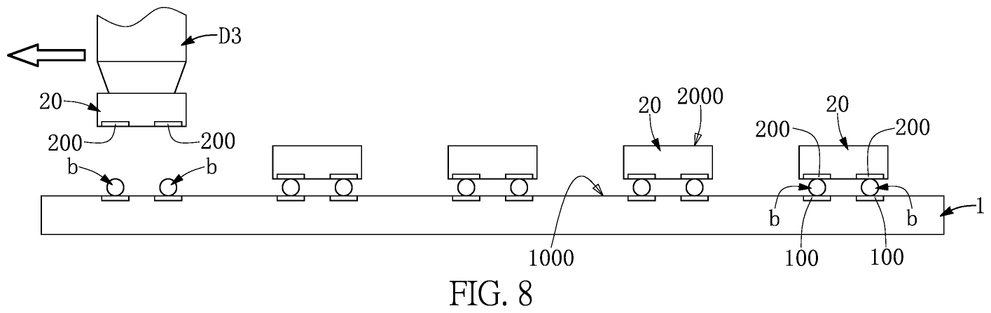

More particularly, referring to FIG. 1, FIG. 8, FIG. 10 and FIG. 11, the step S200 of transferring the light-emitting chips 20 to the circuit substrate 1 further includes: placing each of the light-emitting chips 20 on the two initial conductive materials b of the circuit substrate 1 by a chip pick-and-place device D3, so that two conductive contacts 200 of each of the light-emitting chips 20 are respectively electrically connected to two conductive pads 100 of the circuit substrate 1 through the two corresponding initial conductive materials b (step S200(A)).

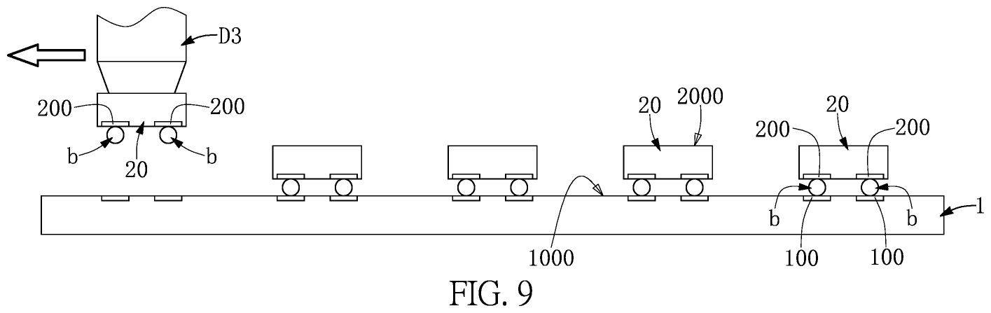

More particularly, referring to FIG. 1, FIG. 9, FIG. 10 and FIG. 11, the step S200 of transferring the light-emitting chips 20 to the circuit substrate 1 further includes: respectively placing the two initial conductive materials b that are carried by each of the light-emitting chips 20 on two conductive pads 100 of the circuit substrate 1 by a chip pick-and-place device D3, so that two conductive contacts 200 of each of the light-emitting chips 20 are respectively electrically connected to the two conductive pads 100 of the circuit substrate 1 through the two corresponding initial conductive materials b (step S200(B)).

For example, in one embodiment, the light-emitting chip 20 can be a micro LED chip without a base layer, and the micro LED chip includes a p-type semiconductor layer, a light-emitting layer disposed on the p-type semiconductor layer, and an n-type semiconductor layer disposed on the light-emitting layer. In addition, in another embodiment, the light-emitting chip 20 may also be a mini LED chip that includes a base layer, a p-type semiconductor layer disposed on the base layer, a light-emitting layer disposed on the p-type semiconductor layer, and an n-type semiconductor layer disposed on the light-emitting layer. However, the aforementioned description of the second embodiment is merely an example and is not meant to limit the scope of the present disclosure.

For example, the initial conductive material b or the conductive material B can be a solder ball, solder paste or any soldering material, and the leveling substrate F can be a light-transmitting plate or an opaque plate, such as a plastic plate, a glass plate or a pressing plate made of any material. In addition, the carrier device D1 can be a nozzle, a gripper or a carrying device for carrying or driving the leveling substrate F, and the carrier device D1 does not affect the heating of the conductive materials B by the heating device D2. Moreover, the heating device D2 can be a laser heater, an infrared (IR) heater, a microwave heater or any heater for providing heat energy to heat the conductive material B. However, the aforementioned description of the second embodiment is merely an example and is not meant to limit the scope of the present disclosure.

More particularly, as shown in FIG. 14, the second embodiment of the present disclosure provides a light-emitting chip carrying structure S including a circuit substrate 1 and a light-emitting group 2. The circuit substrate 1 includes a plurality of conductive pads 100 and a plurality of conductive materials B respectively disposed on the conductive pads 100. In addition, the light-emitting group 2 includes a plurality of light-emitting chips 20, and each of the light-emitting chips 20 includes two conductive contacts 200 respectively electrically contacting the two corresponding conductive materials B. Therefore, a plurality of distances D each defined between a light-emitting surface 2000 of each of the light-emitting chips 20 and a top surface 1000 of the circuit substrate 1 are the same, so that the light-emitting surfaces 2000 of the light-emitting chips 20 relative to the top surface 1000 of the circuit substrate 1 have the same flatness, and the light-emitting surfaces 2000 of the light-emitting chips 20 are located in/on a same plane P. It should be noted that as shown in FIG. 11 and FIG. 12, when a leveling substrate F concurrently presses the light-emitting surfaces 2000 of the light-emitting chips 20 by a carrier device D1, the distances D each defined between the light-emitting surface 2000 of each of the light-emitting chips 20 and the top surface 1000 of the circuit substrate 1 are the same.

### Beneficial Effects of Embodiments

In conclusion, by virtue of “the circuit substrate 1 including a plurality of conductive pads 100 and a plurality of conductive materials B respectively disposed on the conductive pads 100”, “the light-emitting group 2 including a plurality of light-emitting chips 20, and each of the light-emitting chips 20 including two conductive contacts 200 respectively electrically contacting the two corresponding conductive materials B” and “a plurality of distances D each defined between a light-emitting surface 2000 of each of the light-emitting chips 20 and a top surface 1000 of the circuit substrate 1 being the same”, the light-emitting surfaces 2000 of the light-emitting chips 20 relative to the top surface 1000 of the circuit substrate 1 have the same flatness, and the light-emitting surfaces 2000 of the light-emitting chips 20 are located in the same plane P.

Furthermore, by virtue of “driving a leveling substrate F to concurrently press the light-emitting chips 20 by a carrier device D1, so that a plurality of distances D each defined between a light-emitting surface 2000 of each of the light-emitting chips 20 and a top surface 1000 of the circuit substrate 1 are the same” and “while the light-emitting chips 20 are pressed by the leveling substrate F, using a heating device D2 to fix the light-emitting chips 20 on the circuit substrate 1”, the light-emitting surfaces 2000 of the light-emitting chips 20 relative to the top surface 1000 of the circuit substrate 1 have the same flatness, and the light-emitting surfaces 2000 of the light-emitting chips 20 are located in the same plane P.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described so as to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of manufacturing a light-emitting chip carrying structure, comprising:
transferring a plurality of light-emitting chips to a circuit substrate such that each of the light-emitting chips is electrically connected to the circuit substrate through two of a plurality of initial conductive materials;
driving a leveling substrate to concurrently press the light-emitting chips such that a plurality of distances each defined between a light-emitting surface of each of the light-emitting chips and a top surface of the circuit substrate are the same;
while the light-emitting chips are pressed by the leveling substrate, heating a plurality of conductive materials so as to fix each of the light-emitting chips on the two corresponding conductive materials; and
removing the leveling substrate.

2. The method according to claim 1, wherein the step of transferring the light-emitting chips to the circuit substrate further comprises:
placing the light-emitting chips on an adhesive layer of the leveling substrate; and
moving the leveling substrate so as to place each of the light-emitting chips on the two corresponding initial conductive materials of the circuit substrate.

3. The method according to claim 2, wherein two conductive contacts of each of the light-emitting chips are respectively electrically connected to two conductive pads of the circuit substrate by the two corresponding initial conductive materials.

4. The method according to claim 1, wherein the step of transferring the light-emitting chips to the circuit substrate further comprises:
placing the light-emitting chips on an adhesive layer of the leveling substrate, wherein each of the light-emitting chips carries the two corresponding initial conductive materials; and
moving the leveling substrate so as to respectively place the two initial conductive materials of each of the light-emitting chips on two conductive pads of the circuit substrate.

5. The method according to claim 4, wherein two conductive contacts of each of the light-emitting chips are respectively electrically connected to the two corresponding conductive pads through the two corresponding initial conductive materials.

6. The method according to claim 1, wherein the step of transferring the light-emitting chips to the circuit substrate further comprises:
placing each of the light-emitting chips on the two initial conductive materials of the circuit substrate.

7. The method according to claim 6, wherein two conductive contacts of each of the light-emitting chips are respectively electrically connected to two conductive pads of the circuit substrate through the two corresponding initial conductive materials.

8. The method according to claim 1, wherein the step of transferring the light-emitting chips to the circuit substrate further comprises:
respectively placing the two initial conductive materials that are carried by each of the light-emitting chips on two conductive pads of the circuit substrate.

9. The method according to claim 8, wherein two conductive contacts of each of the light-emitting chips are respectively electrically connected to the two conductive pads of the circuit substrate through the two corresponding initial conductive materials.

10. The method according to claim 1, wherein the conductive materials are concurrently heated by using a heating device, and the heating device is one of a laser heater, an infrared heater and a microwave heater for providing heat energy to heat the conductive materials.

11. A method of manufacturing a light-emitting chip carrying structure, comprising:
transferring a plurality of light-emitting chips to a circuit substrate;
driving a leveling substrate to concurrently press the light-emitting chips such that a plurality of distances each defined between a light-emitting surface of each of the light-emitting chips and a top surface of the circuit substrate are the same;
while the light-emitting chips are pressed by the leveling substrate, fixing each of the light-emitting chips on the circuit substrate; and
removing the leveling substrate.

12. The method according to claim 11, wherein the step of transferring the light-emitting chips to the circuit substrate further comprises:
placing the light-emitting chips on an adhesive layer of the leveling substrate; and
moving the leveling substrate so as to place each of the light-emitting chips on two corresponding initial conductive materials of the circuit substrate.

13. The method according to claim 12, wherein two conductive contacts of each of the light-emitting chips are respectively electrically connected to two conductive pads of the circuit substrate by the two corresponding initial conductive materials.

14. The method according to claim 11, wherein the step of transferring the light-emitting chips to the circuit substrate further comprises:
placing the light-emitting chips on an adhesive layer of the leveling substrate, wherein each of the light-emitting chips carries two initial conductive materials; and
moving the leveling substrate so as to respectively place the two initial conductive materials of each of the light-emitting chips on two conductive pads of the circuit substrate.

15. The method according to claim 14, wherein two conductive contacts of each of the light-emitting chips are respectively electrically connected to the two corresponding conductive pads through the two corresponding initial conductive materials.

16. The method according to claim 11, wherein each of the light-emitting chips is fixed on the circuit substrate by using a heating device, and the heating device is one of a laser heater, an infrared heater and a microwave heater.

17. A light-emitting chip carrying structure, comprising:
a circuit substrate including a plurality of conductive pads and a plurality of conductive materials respectively disposed on the conductive pads; and
a light-emitting group including a plurality of light-emitting chips, wherein each of the light-emitting chips includes two conductive contacts respectively electrically contacting the two corresponding conductive materials, and a plurality of distances each defined between a light-emitting surface of each of the light-emitting chips and a top surface of the circuit substrate are the same, so that the light-emitting surfaces of the light-emitting chips relative to the top surface of the circuit substrate have the same flatness, and the light-emitting surfaces of the light-emitting chips are located in a same plane.

18. The light-emitting chip carrying structure according to claim 1, wherein, when a leveling substrate concurrently presses the light-emitting surfaces of the light-emitting chips by a carrier device, the distances each defined between the light-emitting surface of each of the light-emitting chips and the top surface of the circuit substrate are the same.
